(19) United States
(12) Patent Application Publication
(10) Pub. No.: US 2002/0022277 A1
(43) Pub. Date: Feb. 21, 2002

(54) Ferroelectric memory having dielectric layer of siof and method for fabricating the dielectric layer

(76) Inventors: Young-soo Park, Kyungki-do (KR); In-sook Yi, Kyungki-do (KR)

Correspondence Address: THE LAW OFFICES OF, EUGENE M. LEE, P.L.L.C., 2111 WILSON BOULEVARD, SUITE 1200, ARLINGTON, VA, 22201, US

(21) Appl. No.: 09/570,013

(22) Filed: May 12, 2000

(30) Foreign Application Priority Data
Jul. 16, 1999 (KR) 99-28906

(51) Int. Cl. H01L 21/00

(52) U.S. Cl. 438/3; 365/1

(57) ABSTRACT

A ferroelectric memory having a dielectric layer comprised of SiOF, and a method for fabricating the SiOF dielectric layer are provided. Degradation in the ferroelectric properties due to hydrogen atoms can be prevented by depositing a SiOF dielectric layer using SiF₄, instead of depositing a SiO₂ dielectric layer, which has been conventionally used. The ferroelectric memory device, and the method of making the device, provide a stabilized device having less or no degradation in the ferroelectric properties.

### BACKGROUND OF THE INVENTION

1. Field of the Invention

The present invention relates to a ferroelectric memory having a dielectric layer including SiOF, free of hydrogen bonds, and to a method for fabricating the SiOF-containing dielectric layer using a source gas that does not contain hydrogen bonds. The absence of hydrogen atoms during fabrication of the ferroelectric memory prevents degradation of the physical properties of the ferroelectric memory

2. Description of the Related Art

It often is necessary to electrically insulate metal electrodes from each other in semiconductor devices. A silicon oxide film is typically the most widely used material for the purpose of effecting electrical insulation between the metal electrodes. This is primarily because the silicon oxide (SiO₂) film has excellent insulating characteristics and a low dielectric constant. In order to fabricate such a silicon oxide film, however, a hydrogen-bonded compound such as silane (SiH₄) or tetraethoxy silane (TEOS) (Si(OC₂H₅)₄) is used. As a consequence, impurities such as carbon (C), water (H₂O), Silanol (Si—OH), Si—H, and the like, usually are contained in the silicon oxide film.

Hydrogen atoms, water or silanol may give rise to problems such as thermoelectric effects, threshold voltage transition, or deterioration of mutual conductance characteristics, as proposed by Y. S. Obeng, K. G. Steiner, A. N. Velaga and C. S. Pai, in “Dielectric Materials for Advanced VLSI and ULSI Technologies”, AT&T Technology Journal, Vol. 73, No. 94 (1994), and P. A. Flinn, D. S. Gardner and W. D. Nix, in “Measurement and Interpretation of Stress in Aluminum-Based Metallization as a Function of Thermal History”, IEEE Transactions on Electron Devices, Vol. ED34, No. 6897 (1987). In particular, in the case of fabricating a semiconductor device using a ferroelectric material, the adverse effects of these impurities, (e.g., hydrogen atoms), on the semiconductor device become more severe, and the semiconductor device may lose its ferroelectric characteristics.

A ferroelectric memory device usually is formed such that platinum (which is to be used as an upper electrode) is deposited on an oxide-based ferroelectric thin film. That is to say, the ferroelectric memory device has a structure similar to that shown in FIG. 1, but is different from the structure shown in FIG. 1 in that a silicon oxide layer is used as the dielectric layer 7. Platinum used as an upper electrode can give rise to a catalytic reaction that decomposes hydrogen molecules into hydrogen atoms, so that the activated hydrogen atoms are diffused into the ferroelectric thin film from the lower portion of the upper electrode. This decomposition and diffusion of hydrogen atoms deteriorates the ferroelectric characteristics, as proposed by Y. Fujisaki, K. K. Abdelghafar, Y. Shimamoto and H. Miki, in “The Effects of the Catalytic Nature of Capacitor Electrodes on the Degradation Ferroelectric Pb(Zr, Ti)0₃ Thin Films during Reductive Ambient Annealing”, Journal of Applied Physics, Vol. 82, No. 341 (1997), K. K. Abdelghafar, H. Miki, K. Torii and Y. Fujiasaki, in “Electrode-Induced Degradation of Pb(Zr, Ti_{1/x}))O₃ (PZT) Polarization Hysteresis Characteristics in Pt/PZT/Pt Ferroelectric Thin Film Capacitors”, Applied Physics Letter, Vol. 69, No. 3188 (1996), and J. P. Han and T. P. Ma, in “Electrode Dependence of Hydrogen-induced Degradation in Ferroelectric Pb(Zr, Ti)O₃ and SrBi₂Ta₂O₉ Thin Films”, Applied Physics Letter, Vol. 71, No. 1267 (1997).

Thus, the ferroelectric characteristics may be greatly deteriorated if the structure in which the upper portion of platinum is exposed is thermally treated at a high temperature under a hydrogen atmosphere, or if a silicon oxide film is deposited thereon so that hydrogen atoms are generated. It has been found to be necessary to perform the deposition process at a low temperature in order to minimize the influence of the hydrogen atoms generated while the silicon oxide film is deposited. If the deposition temperature is lowered, however, processing by-products such as Si—H, Si—OH, H₂O, and the like are produced in the silicon oxide film. Moreover, after depositing the silicon oxide film, heat treatment must be performed at a temperature of about 500° C. to avoid damaging the device by the plasma generated while etching the electrode/ferroelectric material, or while depositing the silicon oxide film. Here, hydrogen bonds existing within the silicon oxide film are broken which in turn degrade the ferroelectric characteristics of the lower portion of the platinum electrode. Thus, one cannot avoid degradation of the characteristics of a ferroelectric device due to the presence of hydrogen atoms when depositing an oxide layer, or during subsequent annealing using a source gas having hydrogen bonds.

FIG. 2 reveals hysteresis curves illustrating the change in the polarization of a ferroelectric capacitor, before and after deposition of SiO₂. In FIG. 2, SiO₂ is deposited as a dielectric layer, as in a conventional ferroelectric memory capacitor, instead of a SiOF dielectric layer. Degradation of the ferroelectric material is clearly shown in FIG. 2. FIG. 2 shows the polarization characteristics of a ferroelectric capacitor manufactured using a SiH₄ source gas and N₂O, which are conventionally used for depositing the SiO₂ dielectric layer on the ferroelectric capacitor. The polarization characteristics of the ferroelectric capacitor are shown in FIG. 2 when the SiO₂ dielectric layer was deposited with a varying flow rate of SiH₄. The dielectric layer was deposited using an electron cyclone resonance (ECR) plasma chemical vapor deposition apparatus under the following processing conditions: a microwave power of 600 W; a deposition pressure of 2 mTorr; an Ar flow rate of 5 sccm; and a N₂O flow rate of 50 sccm. While varying the SiH₄ flow rate to 1 sccm, 3 sccm and 5 sccm, the thickness of the deposited layer was kept constant at about 1000 Å. In the drawing, the ordinate indicates the polarization and the abscissa indicates the voltage applied after deposition of SiO₂.

The hysteresis loop indicated by the thick solid line in FIG. 2 represents the polarization of the ferroelectric capacitor before forming the SiO₂ dielectric layer, and the hysteresis loop indicated by a single dashed line represents the polarization of the ferroelectric capacitor having the SiO₂ dielectric layer deposited thereon with a SiH₄ flow rate of 1 sccm. The hysteresis loop indicated by a dotted line represents the polarization of the ferroelectric capacitor having the SiO₂ dielectric layer deposited thereon with a SiH₄ flow rate of 3 sccm, and the hysteresis loop indicated by a thin solid line represents the polarization of the ferroelectric capacitor having the SiO₂ dielectric layer deposited thereon with a SiH₄ flow rate of 5 sccm. From these hysteresis curves showing the voltage dependency of the change in the polarization of a ferroelectric capacitor, it can be seen that the polarization behavior of the ferroelectric capacitor is degraded, when compared to the initial capacitor without the SiO₂ dielectric layer deposited thereon.

Therefore, if a dielectric layer is deposited using a SiH₄ source gas (as is conventional), the ferroelectric memory characteristics are degraded. This in turn impedes the ability of the ferroelectric capacitor to function as a memory device, because hydrogen atoms originating from the deposition source gas containing hydrogen bonds (e.g., SiH₄) diffuse into the capacitor and hence, degrade the physical properties of the ferroelectric memory.

### SUMMARY OF THE INVENTION

It is a feature of an embodiment of the present invention to solve the above problems by providing a ferroelectric memory having a dielectric layer comprised of SiOF, which is free of hydrogen bonds. The invention is capable of minimizing degradation in the physical properties of the ferroelectric memory because there are no hydrogen atoms present when the dielectric layer is formed or during annealing, which typically takes place after forming the dielectric layer.

It is another feature of an embodiment of the present invention to provide a method of forming a ferroelectric memory having a dielectric layer comprised of SiOF, which can suppress degradation in the ferroelectric characteristics because there are no hydrogen atoms present during the course of forming the dielectric layer. In accordance with this embodiment of the invention, the dielectric layer is formed using a source gas that does not have a hydrogen bond, and it is formed after forming an upper electrode of the ferroelectric memory. Forming the dielectric layer in this manner can avoid degradation in the ferroelectric characteristics that can occur when hydrogen atoms diffuse into the dielectric layer during a subsequent annealing process. The ferroelectric characteristics are not degraded because there are no hydrogen atoms formed during formation of the dielectric layer.

In accordance with these and other features of various embodiments of the invention, there is provided a ferroelectric memory device having ferroelectric capacitors each comprising a lower electrode having at least an exposed portion, a ferroelectric layer disposed on the lower electrode and having at least an exposed portion, and an upper electrode disposed on the ferroelectric layer. The ferroelectric memory device further comprises a SiOF dielectric layer disposed on the upper electrode, the exposed portion of the ferroelectric layer and the exposed portion of the lower electrode.

In accordance with an additional feature of an embodiment of the invention, there is provided a method for forming a SiOF dielectric layer of a ferroelectric memory device comprising first providing a semiconductor substrate. A plurality of ferroelectric capacitors then can be formed on the semiconductor substrate, each capacitor comprising a lower electrode having at least an exposed portion, a ferroelectric layer disposed on the lower electrode and having at least an exposed portion, and an upper electrode disposed on the ferroelectric layer. Finally, the method includes depositing a SiOF dielectric layer between and on the ferroelectric capacitors using a predetermined flow rate of SiF₄.

### BRIEF DESCRIPTION OF THE DRAWINGS

The above features and advantages of the present invention will become more apparent by describing in detail preferred embodiments thereof with reference to the attached drawings in which:

FIG. 1 illustrates a vertical section view schematically showing a capacitor of a ferroelectric memory having a SiOF dielectric layer according to the present invention;

FIG. 2 is a graph showing the change in the polarization of a ferroelectric capacitor before and after depositing silicon oxide (SiO₂) as the dielectric layer (e.g., a conventional ferroelectric memory capacitor), instead of SiOF as the dielectric layer of FIG. 1 (e.g., the inventive ferroelectric memory capacitor);

FIG. 3 is a graph showing the change in the polarization of a ferroelectric capacitor before and after depositing SiOF as a dielectric layer, as shown in FIG. 1;

FIG. 4 shows hysteresis curves illustrating the change in 2Pr values of ferroelectric capacitors having a SiO₂ layer and a SiOF layer deposited thereon, and the change in 2Pr values of a ferroelectric capacitor after annealing the deposited SiOF layer;

FIGS. 5A through 5C are scanning electron microscope (SEM) photographs of a ferroelectric capacitor having a SiOF layer deposited thereon according to a change in the flow rate of SiF₄ into a deposition chamber. FIG. 5A illustrates the embodiment where the SiF₄ flow rate is 1 sccm, the SiF₄ flow rate is 3 sccm in FIG. 5B, and FIG. 5C illustrates the embodiment where the SiF₄ flow rate is 5 sccm;

FIGS. 6A and 6B are enlarged SEM photographs illustrating the profiles of a ferroelectric capacitor having a SiOF layer deposited thereon, in which FIG. 6A illustrates the embodiment where the SiF₄ flow rate is 3 sccm, and the SiF₄ flow rate is 5 sccm in FIG. 6B; and

FIGS. 7A and 7B are SEM photographs illustrating profiles of a ferroelectric capacitor to which a method for suppressing columnar growth of the SiOF layer shown in FIG. 6B is applied. In FIG. 7A, TiO₂ coated and then the SiOF layer is deposited with a SiF₄ flow rate of 5 sccm. In FIG. 7B, a SiOF layer is primarily coated with a flow rate of 1 sccm, and the SiOF layer then is deposited completely with a SiF₄ flow rate of 5 sccm.

### DESCRIPTION OF THE PREFERRED EMBODIMENTS

Korean Patent Application No. 99-28906, filed on Jul. 16, 1999, and entitled: “Ferroelectric Memory Having Dielectric Layer of SiOF and Method for Fabricating the Dielectric Layer,” is incorporated by reference herein in its entirety. A ferroelectric memory having a SiOF dielectric layer according to various preferred embodiments of the present invention, and a method for forming the dielectric layer will now be described in detail with reference to the accompanying drawings. The thicknesses and number of respective layers described herein are preferred embodiments, and skilled artisans will appreciate that additional layers and various thicknesses of the layers are suitable for use in the invention. In addition, the particular flow rates of various materials used to form certain layers of the ferroelectric memory device are preferred, and hence, skilled artisans will appreciate that the flow rates can be varied as well without departing from the spirit of the invention. Finally, the materials described herein that are used to form the respective layers are preferred, and other materials, or materials in addition to those described, also may be used in the invention.

It is preferred to form a silicon oxide-containing layer using a source gas that does not have hydrogen bonds in order to eliminate or ameliorate any deterioration in the characteristics of various ferroelectric devices having a ferroelectric memory. This is because deterioration in the characteristics of these devices is due to the presence of hydrogen atoms during their formation. Silicon tetrafluoride (SiF₄) can be used as a main source gas, which in turn can be reacted with an oxygen-containing gas (or oxygen) to form a SiOF layer as the dielectric layer. The ferroelectric device then is fundamentally prevented from deteriorating due to the reaction with hydrogen atoms during the course of forming the dielectric layer, and/or after forming the dielectric layer.

An embodiment of the present invention relates to a ferroelectric memory device having ferroelectric capacitors each comprising a lower electrode having at least an exposed portion, a ferroelectric layer disposed on the lower electrode and having at least an exposed portion, and an upper electrode disposed on the ferroelectric layer. The ferroelectric memory device further comprises a SiOF dielectric layer disposed on the upper electrode, the exposed portion of the ferroelectric layer and the exposed portion of the lower electrode.

It is preferred in this embodiment of the present invention that the ferroelectric layer be comprised of at least one material selected from barium strontium titanate, lead zirconate titanate, lead lanthanum titanate, lead lanthanum zirconate titanate, bismuth titanate, potassium tantalate, lead scandium tantalate, lead niobate, lead zinc niobate, potassium niobate, lead magnesium niobate, and various mixtures and/or combinations thereof. The upper electrode preferably is comprised of at least one material selected from platinum (Pt), palladium (Pd), iridium (Ir), rhodium (Rh), and various mixtures and/or combinations thereof.

When the upper electrode is comprised of Pt, it is preferred that there further be provided an additional dielectric layer comprised of at least one material selected from TiO₂, Al₂O₃, ZrO₂, and various mixtures and/or combinations thereof. In addition, when the upper electrode is comprised of Pt, the SiOF dielectric layer preferably has a double-layered structure stacked on the Pt upper electrode, in which a first SiOF dielectric layer is obtained by flowing a SiF₄ gas with a flow rate of less than or equal to 3 sccm, and then a second SiOF dielectric layer is obtained by flowing the SiF₄ gas with a flow rate of greater than 3 sccm.

Another embodiment of the invention relates to a method for forming a SiOF dielectric layer of a ferroelectric memory device comprising first providing a semiconductor substrate. A plurality of ferroelectric capacitors then can be formed on the semiconductor substrate, each capacitor comprising a lower electrode having at least an exposed portion, a ferroelectric layer disposed on the lower electrode and having at least an exposed portion, and an upper electrode disposed on the ferroelectric layer. Finally, the method includes depositing a SiOF dielectric layer between and on the ferroelectric capacitors using a predetermined flow rate of SiF₄.

In this embodiment of the present invention, the ferroelectric layer and the upper electrode preferably are comprised of the materials described above. The upper electrode preferably is formed by a process selected from an electron magnetic resonance plasma method, a radio frequency (RF) plasma method, a helical plasma method and an organometallic chemical vapor deposition method. In this embodiment, when the upper electrode is comprised of Pt, the SiOF layer preferably is deposited by depositing a first SiOF dielectric layer on the Pt upper electrode to a thickness of 230 Å or greater by flowing a SiF₄ gas with a flow rate of less than or equal to 3 sccm, and then depositing a second SiOF dielectric layer on the first SiOF dielectric layer by flowing a SiF₄ gas with a flow rate of greater than 3 sccm. It also is preferred in this embodiment of the invention that, when the upper electrode is comprised of Pt, the method further comprises forming an additional dielectric layer on the Pt upper electrode before deposition of the SiOF dielectric layer. The additional dielectric layer preferably is comprised of at least one material selected from the group consisting of TiO₂, Al₂O₃, ZrO₂, and mixtures or combinations thereof.

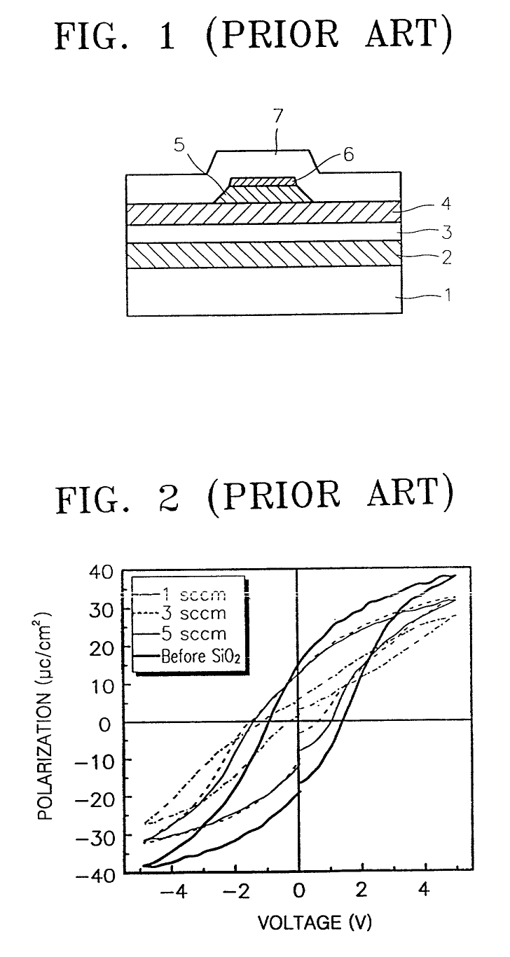

Forming the dielectric layer will now be described in detail by the schematic structure of a ferroelectric memory. FIG. 1 is a vertical sectional view schematically showing a ferroelectric memory capacitor having a SiOF dielectric layer deposited thereon according to an embodiment of the present invention. As shown in FIG. 1, the ferroelectric memory includes a SiOF dielectric layer 7 that does not contain hydrogen atoms, which is formed on ferroelectric capacitors. Each of the ferroelectric capacitors preferably includes a lower electrode 4 having at least an exposed portion, a ferroelectric layer 5 disposed on lower electrode 4 and having at least an exposed portion, and an upper electrode 6 disposed on the ferroelectric layer. The ferroelectric capacitors electrically insulate the ferroelectric capacitors from each other. In other words, to attain insulation between the ferroelectric capacitors 4, 5 and 6, the SiOF dielectric layer 7 is formed on the upper electrode 6, the exposed portion of ferroelectric layer 5, and the exposed portion of the lower electrode 4.

In the above-described structure, the ferroelectric layer 5 preferably is made of at least one material or a combination or mixture of at least two materials selected from barium strontium titanate, lead zirconate titanate, lead lanthanum titanate, lead lanthanum zirconate titanate, bismuth titanate, potassium tantalate, lead scandium tantalate, lead niobate, lead zinc niobate, potassium niobate and lead magnesium niobate, or combinations thereof. The upper electrode 6 preferably is made of at least one material selected from platinum (Pt), palladium (Pd), iridium (Ir) and rhodium (Rh), or combinations and/or mixtures thereof.

In a particularly preferred embodiment, when upper electrode 6 is formed of Pt, it is preferred that an additional dielectric layer comprised of at least one material selected from TiO₂, Al₂O₃ and ZrO₂, or combinations and/or mixtures thereof, is further formed between the Pt upper electrode 6 and the SiOF dielectric layer 7. Providing the intervening dielectric layer is preferred in this embodiment because of poor polarization characteristics of the ferroelectric capacitor due to columnar growth occurring when the SiOF dielectric layer 7 rapidly grows. In addition, when upper electrode 6 is formed of Pt, the SiOF dielectric layer 7 preferably has a double-layered structure stacked on the Pt upper electrode 6. The double-layered structure preferably includes a first SiOF dielectric layer obtained by flowing a SiF₄ gas with a flow rate of less than or equal to 3 sccm, and a second SiOF dielectric layer obtained by flowing the SiF₄ gas with a flow rate of greater than 3 sccm. Sequentially stacking the respective layers in this manner allows the first SiOF layer to be evenly grown to a thickness of about 1000 Å, and then the second SiOF layer to be rapidly grown to a desired thickness.

A method of making a SiOF dielectric layer useful in a ferroelectric memory according to various embodiments of the present invention will now be described. As shown in FIG. 1, the lower electrode 4, the ferroelectric layer 5, and the upper electrode 6 can be sequentially grown on a semiconductor substrate, typically a silicon substrate 1, and then etched at an appropriate width to form a plurality of ferroelectric capacitors (process a).

Next, the SiOF dielectric layer 7 preferably is deposited between and on the ferroelectric capacitors with a predetermined flow of SiF₄ gas (process b). As described above, a feature of one of the embodiments of the present invention is that a dielectric layer is deposited on the upper electrode 6 using SiF₄ gas, which is free of hydrogen bonds, and an oxygen-containing gas as a source gas, instead of forming a SiO₂ layer. In this embodiment of the present invention, it is preferred that at least one compound selected from O₂, O₃ and a hydrogen-free oxygen compound is used as the oxygen-containing source gas in the process (b) where the SiOF dielectric layer is formed. The SiOF dielectric layer disposed on the upper electrode of a ferroelectric capacitor preferably is formed for insulation between an upper layer and a lower layer, or between metal lines (not shown) after coating the metal lines.

In practice, ferroelectric capacitors in the ferroelectric memory can be formed as follows. First, an adhesion layer 3 for increasing the adhesiveness of a lower electrode 4 may be formed on a semiconductor substrate, preferably a silicon substrate 1, on which a thermal oxide layer 2 is coated. Any material that increases the adhesiveness of lower electrode 4 can be used as the adhesion layer. A typical example of a material useful for forming the adhesion layer is TiO₂.

Next, a lower electrode material preferably is coated on the adhesion layer 3 at a temperature of about 300° C. by a sputtering method, and then a ferroelectric material, such as lead zirconate titanate (PZT), is coated thereon to form ferroelectrode layer 5. In the embodiment shown in FIG. 1, the lower electrode is comprised of layers 3 and 4, but skilled artisans will recognize that lower electrode could be comprised of one layer, or more than 2 layers. The PZT material preferably is coated by a sol-gel method, and then is crystallized at a temperature of about 650° C. under an oxygen atmosphere for about 30 minutes. Materials other than PZT, such as those disclosed above, can be used for ferroelectrode layer 5, as will be appreciated by those skilled in the art. An upper electrode material 6 then can be coated on the crystallized ferroelectric material (PZT), preferably at room temperature, and usually by a sputtering method. Then, the upper electrode material and the ferroelectric material can be etched to a predetermined width to form ferroelectric capacitors that correspond to memory cells.

If a hydrogen-containing source gas is used when the dielectric layer is deposited on the thus-formed ferroelectric capacitors, it is preferred in the invention to deposit the dielectric layer using a source gas free of hydrogen bonds in order to suppress hydrogen atoms from being diffused into the ferroelectric capacitors through the upper electrode.

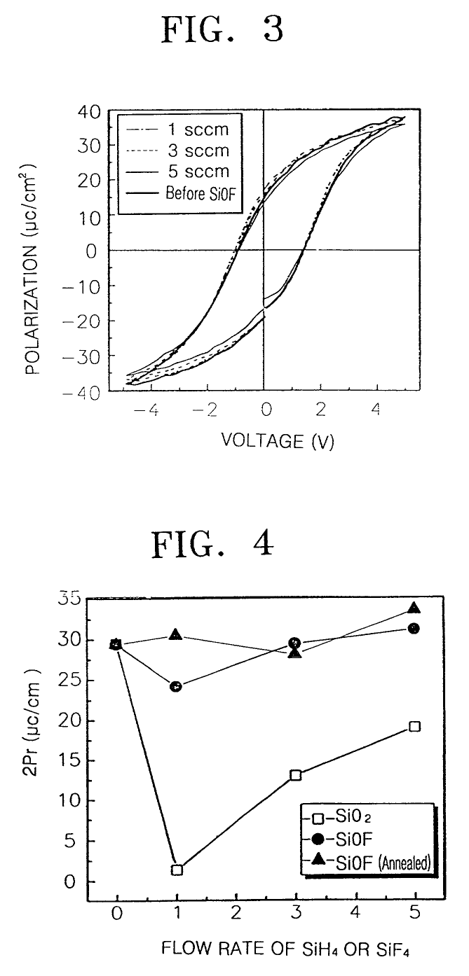

FIG. 3 is a graph showing the change in the polarization of a ferroelectric capacitor before and after depositing SiOF as a dielectric layer, as in the case shown in FIG. 1, where SiF₄ gas is deposited instead of SiH₄ gas. From the results shown in FIG. 3, it is understood that device characteristics are not degraded when the SiOF-containing dielectric layer is deposited by using a SiF₄-containing source gas. Thus, if a dielectric layer is deposited using SiF₄ as a source gas, degradation in the physical properties of a ferroelectric device due to hydrogen atoms generated when using a source gas having hydrogen bonds can be prevented, unlike in the conventional art.

FIG. 4 illustrates various hysteresis curves illustrating the change in 2Pr values of ferroelectric capacitors having a SiO₂ layer and a SiOF layer deposited thereon. The polarization for the conventional ferroelectric capacitors having a SiO₂ layer is shown in FIG. 2, and the polarization for the inventive ferroelectric capacitors having a SiOF layer is shown in FIG. 3. FIG. 4 also illustrates the change in 2Pr values of a ferroelectric capacitor after annealing the deposited SiOF layer.

The curves shown in FIG. 4 illustrate the results shown in FIGS. 2 and 3 more understandably, where the y axes indicate polarization remaining within a capacitor after deposition of a SiO₂ layer and a SiOF layer. In addition, FIG. 4 verifies the degradation in the capacitor characteristics due to separation of F atoms from SiOF by annealing to 500° C. under a nitrogen atmosphere for 10 minutes after depositing the SiOF layer. As shown by the curves indicated by -•- and -▴-, after applying SiOF, the remnant polarization was not reduced even after depositing SiOF or annealing.

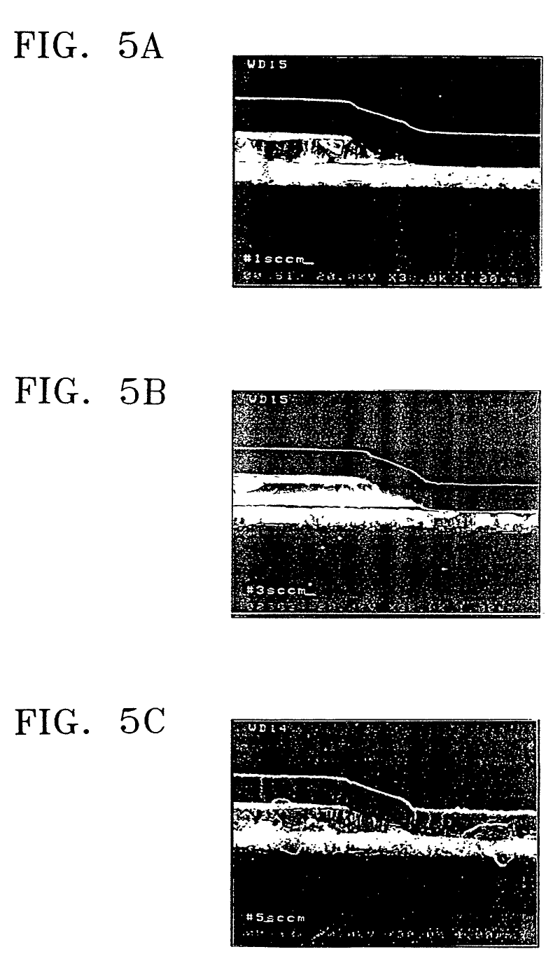

FIGS. 5A through 5C are scanning electron microscope (SEM) photographs of a ferroelectric capacitor having a SIOF layer deposited thereon, depending on the change of the flow rate of SiF₄ flowed into a deposition chamber. In FIG. 5A, the SiF₄ flow rate was 1 sccm, FIG. 5B shows the SEM of a ferroelectric capacitor when the SiF₄ flow rate was 3 sccm, and in FIG. 5C, the SiF₄ flow rate was 5 sccm. As shown in the photographs, a Pt lower electrode is deposited on a silicon substrate to a thickness of about 2700 Å, a PZT ferroelectric layer and a Pt upper electrode then are etched thereon to thicknesses of about 2500 Å and 1000 Å, respectively. The SiOF layer then is coated on these layers.

In this preferred embodiment of the invention, the Pt upper electrode and the PZT ferroelectric layer are not vertically etched, but rather are etched to be substantially smooth layers, (preferably smooth layers). Thus, the SiOF layer grows on a plane where the Pt upper and lower electrodes, and the PZT ferroelectric layer exists. From FIGS. 5A-5C, it can be seen that as the flow rate of SiF₄ increases, the cross-section of the SiOF layer grows from a substantially smooth layer (preferably a smooth layer) to a columnar layer. The SIOF dielectric layer deposited with a flow rate of 5 sccm (FIG. 5C) is nearly perfectly columnar (preferably perfectly columnar).

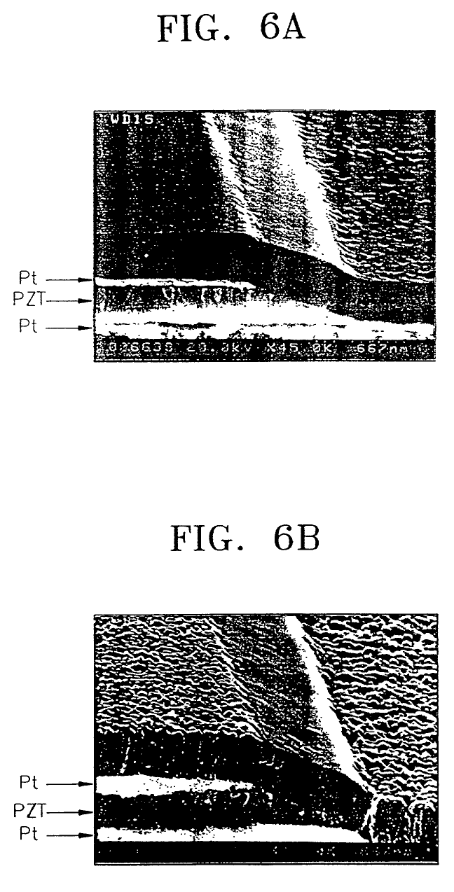

In order to more clearly observe the columnar shape shown in FIG. 5C, the SEM photographs of the cross-section and sloping plane of the SiOF layer deposited with flow rates of 3 sccm and 5 sccm are shown in FIGS. 6A and 6B. As shown in FIG. 6A, the SiOF layer deposited with a SiF₄ flow rate of 3 sccm did not reveal a columnar cross-section and the surface thereof was substantially smooth. However, in the case where the SiF₄ flow rate was 5 sccm, the cross-section of the SiOF layer was nearly perfectly columnar (preferably perfectly columnar), and the surface of this SiOF layer became quite rough.

The columnar cross-section was observed on the Pt upper and lower electrodes. The SiOF layer on the exposed portion of the PZT layer grew smoothly. These results show that the SiOF layer, having been grown with a relatively high flow rate of SiF₄, had an abnormal growth shape. Depositing the SiOF layer with a high rate of SiF₄ therefore is believed to increase the growth rate of a deposited film, and strengthens Si—F bonds within the SiOF layer to impart a low dielectric index. Thus, when a SiOF layer is deposited on a ferroelectric capacitor, it is preferred to develop processes for suppressing columnar growth due to use of a high flow rate of SiF₄.

As shown in FIG. 6B, using the result that the columnar growth was observed only on the Pt lower and upper electrodes, an additional dielectric layer made of a material selected from TiO₂, Al₂O₃ and ZrO₂, or any combination and/or mixtures thereof, can be deposited and then a SiOF dielectric layer deposited thereon. This deposition process preferably obtains a homogenous SiOF dielectric layer, when compared to depositing the SiOF layer directly on the Pt electrodes.

In addition, FIG. 6A illustrates that when SiF₄ was flowed with a low flow rate of 3 sccm or below, no columnar growth was found on the Pt electrodes. Thus, a uniform SiOF layer was thinly deposited with a low SiF₄ flow rate of 3 sccm or below at an initial stage, and then a SiOF dielectric layer was deposited with a high SiF₄ flow rate of greater than 3 sccm in a state where the uniform SiOF layer was coated. This process obtains a homogeneous, preferably an entirely homogeneous, SiOF dielectric layer.

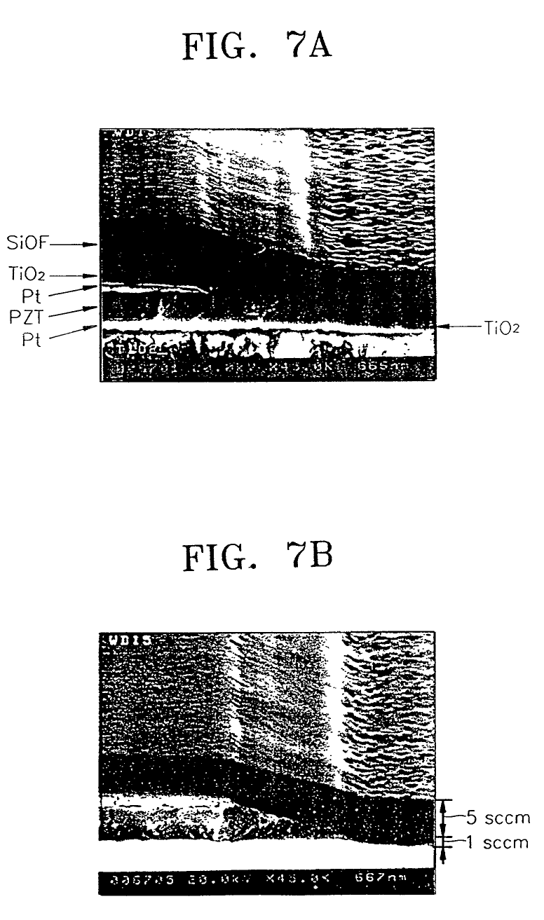

FIGS. 7A and 7B are SEM photographs showing the cross-section and surface of a ferroelectric capacitor illustrating the verification results of the above-described two methods. FIG. 7A is a SEM photograph for the process where TiO₂ first was coated on the upper electrode, and then the SiOF layer was deposited with a SiF₄ flow rate of 5 sccm. FIG. 7B is a SEM photograph for the process where a SiOF layer was primarily coated with a SiF₄ flow rate of 1 sccm, and then the SiOF layer was deposited with a SiF₄ flow rate of 5 sccm.

Compared to FIG. 6B, FIG. 7A shows that no columnar growth was observed on the PT electrodes. Thus, it is understood that columnar growth can be sufficiently suppressed by first depositing various types of dielectric layers, and then depositing a SiOF dielectric layer. Although preferred dielectric layers are described above (e.g., TiO₂, Al₂O₃ and ZrO₂, or any combinations and/or mixtures thereof), skilled artisans will appreciate that any suitable dielectric material may be used for the additional dielectric layer used to suppress columnar growth.

Also, in FIG. 7B, a thin SiOF dielectric layer was initially deposited to a thickness of about 230 Å with a low SiF₄ flow rate of about 1 sccm, and then a SiOF dielectric layer was deposited to a thickness of about 4000 Å with a SiF₄ flow rate of about 5 sccm. Compared to FIG. 6B, in which SiF₄ was continuously flowed with a high flow rate from the initial stage, no columnar growth was shown in FIG. 7B on the cross-section of the SiOF layer, and the surface thereof was smooth.

As described above, in the ferroelectric memory device according to various embodiments of the present invention, degradation in the ferroelectric properties due to the presence of hydrogen atoms can be prevented by depositing a SiOF dielectric layer using SiF₄ as an intermetal dielectric layer, instead of SiO₂ which has been conventionally used. The process of the invention stabilizes the fabrication process of a ferroelectric memory device. Also, when manufacturing a ferroelectric device using a Pt upper electrode, in order to increase the growth rate of a SiOF layer, or to reduce the dielectric constant, a dielectric layer such as TiO₂ which is in addition to the SiOF dielectric layer, preferably is deposited before depositing the SiOF layer with a high flow rate of SiF₄. Alternatively, a SiOF layer initially can be deposited with a low SiF₄ flow rate at an initial stage, and then fully deposited with a high SiF₄ flow rate, thereby suppressing columnar growth on a Pt electrode. This process allows a qualified growth of the SiOF dielectric layer on the Pt electrode.

While the invention has been described with reference to particularly preferred embodiments and figures, those skilled in the art will appreciate that various modifications may be made to the invention without departing from the spirit and scope thereof.

What is claimed is:

1. A ferroelectric memory device having ferroelectric capacitors, each capacitor comprising a lower electrode having at least an exposed portion, a ferroelectric layer disposed on the lower electrode and having at least an exposed portion, and an upper electrode disposed on the ferroelectric layer, wherein the ferroelectric memory device further comprises a SiOF dielectric layer disposed on the upper electrode, the exposed portion of the ferroelectric layer and the exposed portion of the lower electrode.

2. The ferroelectric memory device according to claim 1, wherein the ferroelectric layer is comprised of at least one material selected from the group consisting of barium strontium titanate, lead zirconate titanate, lead lanthanum titanate, lead lanthanum zirconate titanate, bismuth titanate, potassium tantalate, lead scandium tantalate, lead niobate, lead zinc niobate, potassium niobate, lead magnesium niobate, and mixtures or combinations thereof.

3. The ferroelectric memory device according to claim 1, wherein the upper electrode is comprised of at least one material selected from the group consisting of platinum (Pt), palladium (Pd), iridium (Ir), rhodium (Rh), and mixtures or combinations thereof.

4. The ferroelectric memory device according to claim 1, wherein the upper electrode is comprised of Pt, and the ferroelectric memory device further comprises an additional dielectric layer formed of at least one material selected from the group consisting of TiO₂, Al₂O₃, ZrO₂, and mixtures or combinations thereof.

5. The ferroelectric memory device according to claim 1, wherein the upper electrode is comprised of Pt, and the SiOF dielectric layer is comprised of a double-layered structure including a first SiOF dielectric layer obtained by flowing a SiF₄ gas with a flow rate of less than or equal to 3 sccm, and a second SIOF dielectric layer obtained by flowing the SiF₄ gas with a flow rate of greater than 3 sccm.

6. A method for forming a SiOF dielectric layer of a ferroelectric memory device comprising:
providing a semiconductor substrate;
forming a plurality of ferroelectric capacitors on the semiconductor substrate, each ferroelectric capacitors comprising a lower electrode having at least an exposed portion, a ferroelectric layer disposed on the lower electrode and having at least an exposed portion, and an upper electrode disposed on the ferroelectric layer; and
depositing a SiOF dielectric layer between and on the ferroelectric capacitors using a predetermined flow rate of SiF₄.

7. The method according to claim 6, wherein the ferroelectric layer is comprised of at least one material selected from the group consisting of barium strontium titanate, lead zirconate titanate, lead lanthanum titanate, lead lanthanum zirconate titanate, bismuth titanate, potassium tantalate, lead scandium tantalate, lead niobate, lead zinc niobate, potassium niobate, lead magnesium niobate, and mixtures or combinations thereof.

8. The method according to claim 6, wherein the upper electrode is comprised of at least one material selected from the group consisting of platinum (Pt), palladium (Pd), iridium (Ir), rhodium (Rh), and mixtures or combinations thereof.

9. The method according to claim 6, wherein the SiOF dielectric layer is deposited by at least one deposition method selected from the group consisting of an electron magnetic resonance plasma method, a radio frequency (RF) plasma method, a helical plasma method, and an organometallic chemical vapor deposition method.

10. The method according to claim 6, wherein the upper electrode is comprised of Pt, and the SiOF dielectric layer is deposited by a process comprising:
depositing a first SiOF dielectric layer on the Pt upper electrode to a thickness of 230 Å or greater by flowing a SiF₄ gas with a flow rate of less than or equal to 3 sccm; and
depositing a second SiOF dielectric layer on the first SiOF dielectric layer by flowing a SiF₄ gas with a flow rate of greater than 3 sccm.

11. The method according to claim 6, wherein the upper electrode is comprised of Pt, and the method further comprises, before deposition of the SiOF dielectric layer, forming an additional dielectric layer on the upper electrode, whereby the additional dielectric layer is comprised of at least one material selected from the group consisting of TiO₂, Al₂O₃, ZrO₂, and mixtures or combinations thereof.
